(19) United States
(12) Patent Application Publication
(10) Pub. No.: US 2006/0011929 A1
(43) Pub. Date: Jan. 19, 2006

(54) Rotating display device

(76) Inventor: Shuji Inaba, Tokyo (JP)

Correspondence Address: WINSTON & STRAWN LLP, 1700 K STREET, N.W., WASHINGTON, DC, 20006, US

(21) Appl. No.: 11/168,057

(22) Filed: Jun. 25, 2005

Related U.S. Application Data
(60) Provisional application No. 60/584,014, filed on Jun. 29, 2004.

(51) Int. Cl. H01L 27/15

(52) U.S. Cl. 257/82

(57) ABSTRACT

A device for displaying an image is provided. The device includes a hub that is configured to rotate about a first axis and a motor configured to rotate the hub about the first axis. A plurality of light detecting devices attached to the hub and at least one lens configured to direct light toward the light detecting devices are provided. Furthermore, the device includes at least one radial member oriented along a radial axis, the radial member having a first end attached to the hub and a second end. The radial member includes a plurality of light-emitting devices disposed therein, the light emitting devices being oriented along the radial axis. The device also includes a power source operably coupled to the motor, power source and light-emitting devices, wherein the light emitting devices emit light in response to light received by the light detecting devices.

This application claims the benefit of provisional application 60/584,014 filed Jun. 29, 2004, the entire content of which is expressly incorporated herein by reference thereto.

### BACKGROUND OF THE INVENTION

1. Field of the Invention

The present invention relates to a device and method for displaying images. Particularly, the present invention is directed to a device for displaying an image of an observer in real time.

2. Description of Related Art

A variety of methods and systems are known for displaying images for an observer. Certain devices include televisions, display panels, pixelated displays and the like.

U.S. Design Pat. No. 442,497 describes a device that, when rotated at a particular velocity, displays a message to an observer in a narrow annular strip defined by the end edge of the device when it is rotated. However, this device can only display messages at one discrete angular velocity, and can only display a message on a very small surface area as observed by an observer.

While such conventional methods and systems generally have been considered satisfactory for their intended purpose, it is desirable to have a display device that is capable of displaying an image on a large plane that can be viewed easily by an observer. It is also desirable to have a device that is inexpensive and can be used in a variety of areas and applications. There thus remains a continued need for an efficient and economic method and system for displaying images to an observer.

### SUMMARY OF THE INVENTION

The purpose and advantages of the present invention will be set forth in and apparent from the description that follows, as well as will be learned by practice of the invention. Additional advantages of the invention will be realized and attained by the methods and systems particularly pointed out in the written description and claims hereof, as well as from the appended drawings.

To achieve these and other advantages and in accordance with the purpose of the invention, as embodied and broadly described, the invention includes a device for displaying images. The device includes a hub that is configured to rotate about a first axis and a motor configured to rotate the hub about the first axis. A plurality of light detecting devices attached to the hub and at least one lens configured to direct light toward the light detecting devices are provided. Furthermore, the device includes at least one radial member oriented along a radial axis, the radial member having a first end attached to the hub and a second end. The radial member includes a plurality of light-emitting devices disposed therein, the light emitting devices being oriented along the radial axis. The device also includes a power source operably coupled to the motor, power source and light-emitting devices, wherein the light emitting devices emit light in response to light received by the light detecting devices.

In further accordance with the invention, a device as described above is provided, wherein each of the light detecting devices is electrically connected to one or more of the light-emitting devices. At least one transistor can be placed in a circuit with each of the light detecting devices and light emitting devices. Moreover, each of the light detecting devices can be configured to emit light at one or more preselected wavelengths. The light emitting devices can be configured to emit light in a color selected from the group consisting of red, green and blue. Preferably, the light emitting devices are configured to emit light in red, green and blue.

In accordance with still a further aspect of the invention, the light emitting devices can be provided in the form of liquid crystal display devices. Additionally or alternatively, the light emitting devices can include one or more thin-film transistor display devices. Moreover, the light emitting devices can be comprised of a flexible polymeric display device. Furthermore, the light emitting devices can include organic light emitting diodes.

In accordance with another aspect of the invention, the device can include a plurality of lenses configured to direct light toward the light detecting devices. The plurality of lenses can be arranged to create a collimated beam of light that is directed toward the light detecting devices.

In accordance with still another aspect of the invention, the device can further include at least one fiber optic filament, the filament having a first end in optical communication with light directed by the at least one lens and a second end in optical communication with the light detecting devices. Furthermore, the device can include a plurality of fiber optic filaments, wherein a lens is in optical communication with the plurality of fiber optic filaments. Moreover, the device can include a plurality of lenses. At least one of the plurality of lenses can be in optical communication with the second end of a fiber optic element.

In accordance with another aspect of the invention, the device can include a processor and a digital memory device capable of storing data. The device can be configured to display an image representative of an observer. Moreover, the device can be configured to display an image of an observer in superposition with a second image, the second image being stored in the digital memory device and displayed on the light emitting devices by the processor.

In accordance with a further aspect of the invention, a system is provided. The system can include a device as described above that is integrated with a rotating device. The rotating device can be a fan. Moreover, the fan can be a ceiling fan.

The invention also includes a method for displaying images. The method includes providing a device as described above, operating the motor to rotate the hub about the first axis, directing light toward the light detecting devices using the at least one lens, generating an electrical signal by detecting at least a portion of the directed light using the light detecting devices, directing the electrical signal through one or more electrically conductive elements to the light-emitting devices, and emitting light from the light emitting devices.

It is to be understood that both the foregoing general description and the following detailed description are exemplary and are intended to provide further explanation of the invention claimed.

The accompanying drawings, which are incorporated in and constitute part of this specification, are included to illustrate and provide a further understanding of the method and system of the invention. Together with the description, the drawing serves to explain the principles of the invention.

### BRIEF DESCRIPTION OF THE DRAWINGS

FIG. 1 is a partial cross sectional view of a display device in accordance with the invention.

FIG. 2 is a top cross sectional view of a display device in accordance with the invention in combination with an observer.

FIG. 3 is a cut away partial perspective view of an alternative embodiment of a display device in accordance with the invention.

FIG. 4 is a view of a portion of an alternative embodiment of a display device in accordance with the invention.

FIG. 5 is a perspective view of an alternative embodiment of a display device in accordance with the invention.

FIG. 6 is a view of a portion of a display device in accordance with the invention.

FIGS. 7(a)-7(b) are cross-sectional views of a portion of an alternative embodiment of a display device in accordance with the invention.

FIG. 8 is a view of a portion of an alternative embodiment of a display device in accordance with the invention.

FIG. 9 is a view of a portion of another alternative embodiment of a display device in accordance with the invention.

FIG. 10 is a view of a system including a display device in accordance with the invention.

### DETAILED DESCRIPTION OF THE PREFERRED EMBODIMENT

Reference will now be made in detail to the present preferred embodiments of the invention, an example of which is illustrated in the accompanying drawings. The method and corresponding steps of the invention will be described in conjunction with the detailed description of the system.

The device, method and system presented herein may be used for displaying graphic representations. The present invention is particularly suited for displaying an image that is representative of an observer. The device is suitable for use, for example, as a children's toy or for use as an art, design or advertising medium. For example, at a trade show a client could use a device in accordance with the invention that detects and reflects an enlarged image of an observer superimposed over the client's corporate logo.

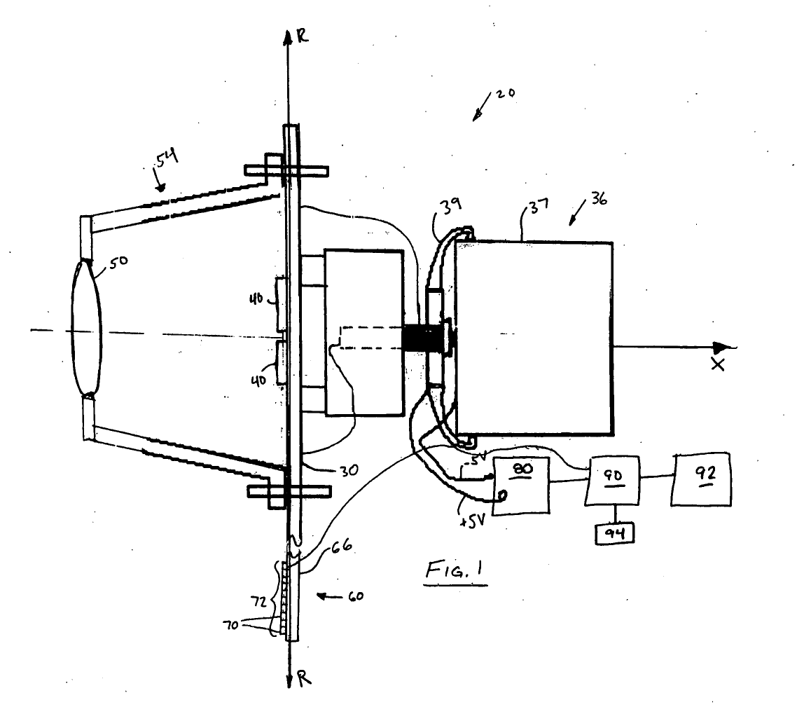

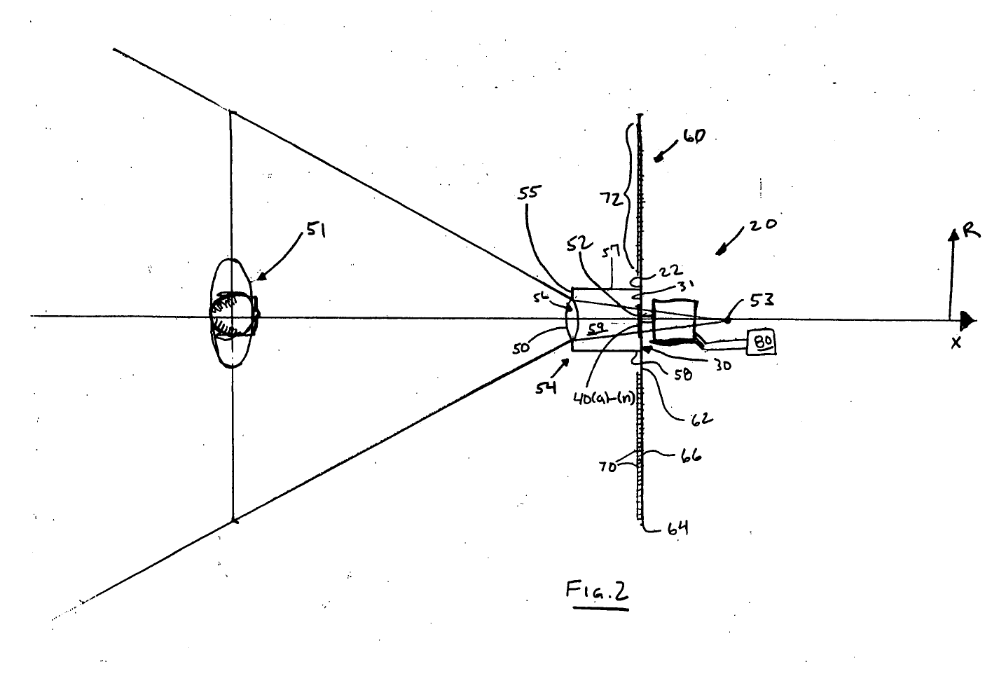

For purpose of explanation and illustration, and not limitation, an exemplary embodiment of a device in accordance with the invention is shown in FIG. 1 and is designated generally by reference character 20. Additional embodiments of the invention or portions thereof are shown in FIGS. 2-10 for purpose of illustration and not limitation. As depicted, the device includes a hub 30 that is configured to rotate about a first axis and a motor 36 configured to rotate the hub 30 about the first axis. A plurality of light detecting devices 40 attached to the hub 30 and at least one lens 50 configured to direct light toward the light detecting devices are provided. Furthermore, the device includes at least one radial member 60 oriented along a radial axis. The radial member 60 includes a plurality of light-emitting devices 70 disposed therein, the light emitting devices being oriented along the radial axis. The device also includes a power source 80 operably coupled to the light detecting devices 40 and light-emitting devices 70, wherein the light emitting devices 70 emit light in response to light received by the light detecting devices 40.

In use, the lens 50 views an object, such as an observer 51, as depicted in FIG. 2. The lens 50 focuses the light reflected by the observer, and directs it to a plurality of light detecting devices 40(a)-40(n) that sense the light. These light sensitive elements are each associated with a light emitting device 70 attached to a radial member 60. As the assembly containing these items is rotated more and more quickly, a composite image of the observer can, in effect, be detected with each revolution of device 20 and be displayed back to the observer 51 in the form of a rasterized image on a circular viewing plane 22 by the light emitting devices 70 as they sweep through a complete revolution in a circular plane.

In accordance with the invention, the device includes a hub that is configured to rotate about a first axis and a motor configured to rotate the hub about the first axis.

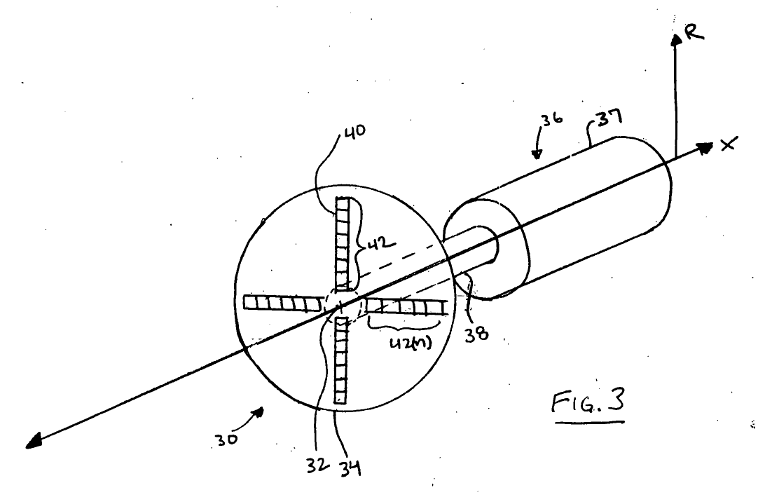

For purposes of illustration and not limitation, as embodied herein and as depicted in FIG. 3, the hub 30 includes a center 32 and an outer periphery 34. Hub 30 is mounted to a drive shaft 38 of a motor 36 that permits hub 38 to rotate about an axis of rotation “X” when motor 36 is actuated. Hub 30 may be permanently attached to motor 36, or may be removably connected, such as by a set screw or other removable connection. Hub 30 is preferably molded from a plastic material, but can also be made from other materials such as metal or fiber-reinforced resin.

In further accordance with the invention, a plurality of light detecting devices attached to the hub are provided.

For purposes of illustration and not limitation, as embodied herein and as depicted in FIG. 3, the light detecting devices 40 are arranged on the hub 30 along a radial axis “R.”

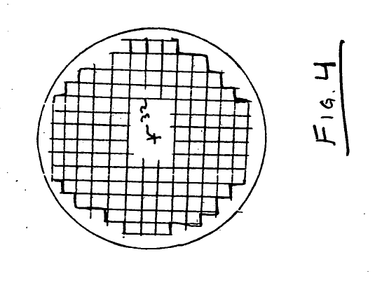

Light detecting devices 40 can be conventional photo detector elements, as are known in the art, phototransistors or can also be provided in the form of photodiodes. Light detecting devices 40 can be arranged in radial strips outwardly from the center of hub 30, or in other ways. A single row 42 of light detecting devices 40 may be provided, or many such strips 42(a)-42(n) can be provided as depicted in FIG. 3. Moreover, if desired, a two-dimensional matrix of light detecting devices can be provided in either Cartesian coordinates (FIG. 4) or radial coordinates as depicted in FIG. 3.

Light detecting devices 40 can be photodiodes, or can be other types of devices (e.g., phototransistors or the like), or other types of light sensitive elements, as are known in the art. Moreover, light detecting devices 40 can be sensitive to a broad range of the spectrum or specific wavelengths. For example, light detecting devices 40 can be sensitive to light outside of visible light in addition to visible light. Thus, it is possible for light detecting devices 40 to be sensitive to infrared light. This can permit for an image of an observer in a dark room to be detected and redisplayed, even though no visible light is reflected from the observer, since the observer gives off body heat in the infrared portion of the spectrum. Moreover, light detecting devices can be provided that detect specific colors of visible light (red, green, blue, etc.) or even other portions of the spectrum (e.g., ultraviolet).

In further accordance with the invention, the device includes a lens configured to direct light toward the light detecting devices. Optionally, a housing can also be provided for holding the lens.

For purposes of illustration and not limitation, as embodied herein and as depicted in FIG. 2, a lens 50 is provided. Lens 50 is configured to direct light reflected by an observer to the light detecting devices 40. This can be accomplished with a single lens 50 that has curvature sufficient to focus light on a focal plane 52 located on the surface 31 of hub 30 that is between the lens and its focal point 53. Depending on the lens(es) used, an image can be inverted by lens 50, which can be corrected for by correlating a row 42 of light detecting elements 40 with a row 72 of light emitting devices 70 that are 180 degrees opposed to one another. Lens 50 is preferably mounted in a cylindrical housing 54 having a flattened first end 55 with an opening 56 in which lens 50 is mounted and a cylindrical wall 57. A second end 58 of housing 54 is affixed to hub 30. Collectively, hub 30, wall 57 and first end 56 define an empty chamber 59, and serve to prevent any light from entering chamber 59 except that entering through lens 50. Housing 54 can be formed separately from hub and attached thereto. Alternatively, wall 57 can be formed integrally with hub 30 and first end 56 can be fitted onto wall 57. Moreover, first end 56 can be integrally formed with lens 50, or first end 56 can be made up entirely of lens 50, with lens 50 fitting into the end of cylindrical wall 57.

In further accordance with the invention, the device includes at least one radial member oriented along a radial axis, the radial member having a first end attached to the hub and a second end.

For purposes of illustration and not limitation, as embodied herein and as depicted in FIG. 2, the device 20 includes a radial member 60 having a first end 62 attached to the hub 30, a second end 64 and an elongate body 66.

Hub 30 can be coupled to radial member 60 in a number of ways. Hub 30 can be integrally formed with radial member 60, such as by plastic injection molding. Suitable materials include various plastics and fiberglass reinforced resins or other composite materials. The radial member 60 can also be formed separately from the hub 30, and be attached thereto by a threaded or snap fit connection, or by adhesive or other bond or weld. Moreover, if housing 54 is provided, one or more radial members 60 can be attached thereto or formed integrally therewith.

In further accordance with the invention, the radial member includes a plurality of light-emitting devices disposed therein, the light emitting devices being oriented along the radial axis.

For purposes of illustration and not limitation, as embodied herein and as depicted in FIG. 2, the light emitting devices 70 are arranged in rows 72 oriented radially on or within elongate body 66 of radial member 60. Light-emitting devices 70 are operably coupled to a light detecting devices 40 and a power source 80 discussed in detail below. Light-emitting devices 70 can be individually mounted in pre-formed recesses in radial member 60, or can be mounted or formed on a flexible circuit board or substrate (not shown), wherein the board or substrate is provided with conductive elements thereon to electrically connect light-emitting devices 70 directly or indirectly with light detecting devices and power source 80 and a processor 90 and/or memory if provided, discussed below. All that is required is that light-emitting devices be able to define discrete areas from which light is emitted.

Light-emitting devices 70 are depicted in FIG. 2 as light-emitting diodes “LED's,” aligned in a radial direction of the radial member 60. However, other various devices and numbers thereof may be used as light-emitting devices 70. For example, light emitting devices 70 may simply be small incandescent light bulbs having a conventional filament. Where a higher amount of light output is necessary other types of lighting elements (e.g., halogen) lights may be used where appropriate for the application. Light emitting devices may also be formed in a manner similar to an active matrix display panel using thin-film transistors (“TFTs”). In accordance with this variation, a multi-pixelated elongate display panel may be provided including dozens or hundreds of TFTs, as may be appropriate depending on the application. This may be connected with processor in a conventional manner as is known in the art. Organic light-emitting diodes may also be employed. Moreover, flexible polymer screens can also be employed similar to the “Polymer Vision”™ display technology available from Philips corporation, which uses thin-film transistors (“TFTs”) mounted on a polymeric material instead of glass, and uses “eInk”™ a system using half black/half white capsules that uses an electrical charge to change the capsule's orientation. Other polymeric films capable of acting as a display medium are also within the scope of the invention.

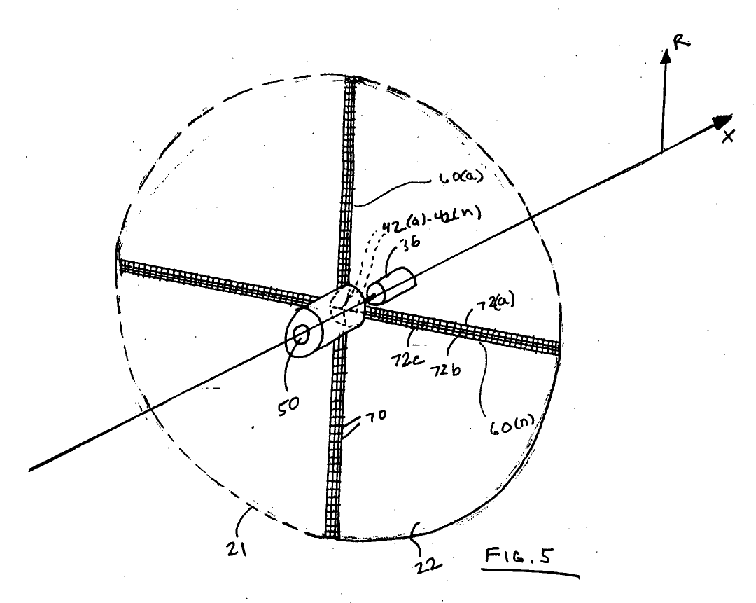

As with the rows 42(a)-42(n) of light detecting devices 40, one or more radial members 60(a)-60(n) can be provided as depicted in FIG. 5. Preferably, the number of rows 42 of light detecting devices 40 are equal in number to the number of radial members 60. This permits each light detecting device 40 in each row 42 to be connected with one or more light emitting devices 70 in rows 72. Thus, light detected by light detecting devices 40 is, in effect, redisplayed through light emitting devices 70. As discussed above, when a single lens 50 is provided the image on focal plane 52 is inverted. Thus, as shown in FIG. 5, a given row 42 of light detecting devices 40 is offset 180 degrees from a row 72 of light emitting devices 72. As device 20 rotates, the light detecting devices 40 sweep through a circular path 21 defining a circular plane 22 and cause corresponding light emitting devices 70 in radial members 60 to light. If device 20 is rotating quickly enough, this results in light emitting devices 70 producing a rasterized image of the observer that is “seen” by lens 50. Thus, the disclosed invention can be thought of as a “mirror.”

In further accordance with the invention, the device also includes a power source operably coupled to the motor, power source and light-emitting devices, wherein the light emitting devices emit light in response to light received by the light detecting devices.

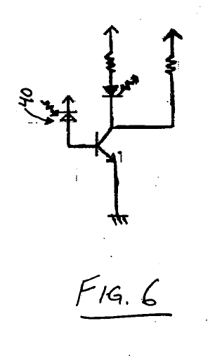

For purposes of illustration and not limitation and as depicted in FIG. 1, power source 80 can be provided in the form of a direct current (“DC”) electrical source. While any suitable voltage can be used, a device in accordance with the invention has been used with a DC source at 5 volts. An exemplary photodiode-transitor-resistor circuit is depicted in FIG. 6. The 5V DC power is provided to each of the circuit components (light detecting device 40 (e.g., photodiode), transistor, light emitting device (e.g., light emitting diode) and resistors by using the shaft 38 of the motor 36 as a negative lead, or ground by connecting an electric lead to the motor casing 37. The positive 5V lead is provided through a bearing 39 that is insulated from the motor shaft 38. This permits a circuit to be completed through each of the circuit components.

A variety of power sources can be used for power source 80. For example, a battery can be used as described herein, or the device can be configured to run off of alternating current as desired. Power source 80 can alternatively be located inside housing 54, or radial member 60. Where device 20 is a part of a larger system, such as a fan, as discussed below, the power source 80 can be located elsewhere within the system, and electrically connected to device either directly or via radio frequency/inductively coupled power transmission.

In accordance with still another aspect of the invention, the device can further include at least one fiber optic filament, the filament having a first end in optical communication with light directed by the at least one lens and a second end in optical communication with the light detecting devices.

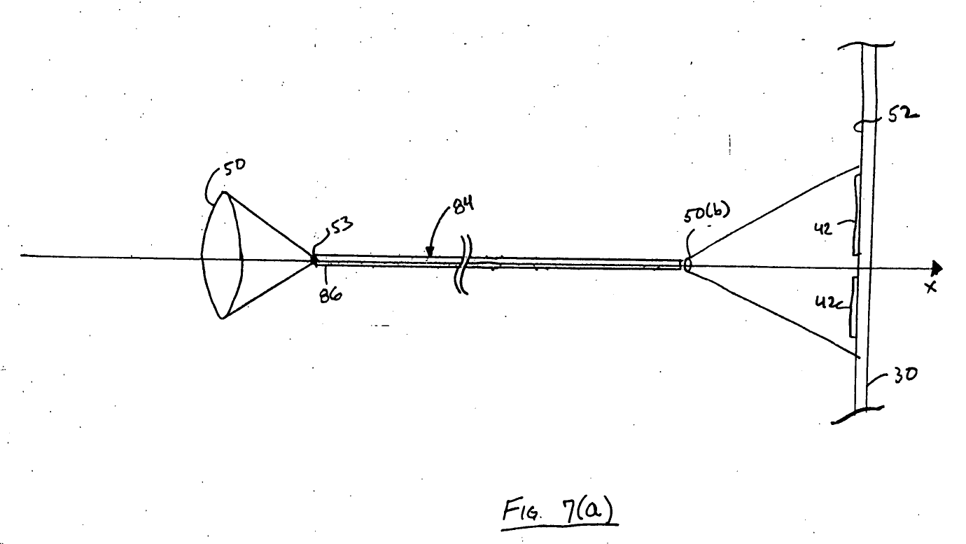

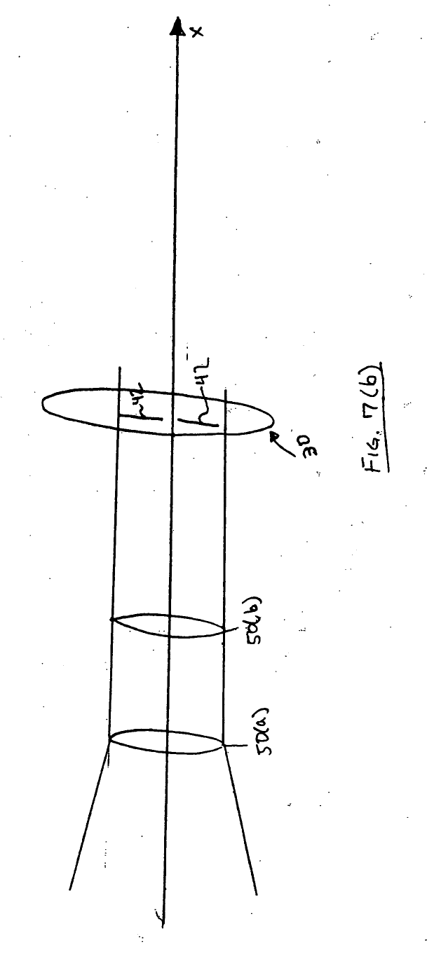

For purposes of illustration and not limitation, as embodied herein and as depicted in FIG. 7(a), a device 20 including a fiber optic filament 84 is provided. Such a fiber optic filament can be used in device 20 if it is desired or necessary to not align lens 50 with focal plane 52 through direct mechanical alignment. Using one or more fiber optic filaments that are configured to transmit light by aligning a first end 86 of filament 84 with focal point 53 of lens 50 can be used to transmit the light to where it is needed.

Moreover, the device 20 can include a plurality of lenses 50(a)-50(n). Lens 50(b) can be in optical communication with a second end 88 of a fiber optic element to permit the light to be diffused onto an array of light sensitive devices 40, as depicted in FIG. 7(a). Moreover, if it is desired to create a collimated beam of light, a first lens 50(a) can gather the light, and a second lens 50(b) can be used to collimate, or straighten the received light into a column as depicted in FIG. 7(b) so that the focal distance between the lenses and light sensitive devices is not critical.

In accordance with another aspect of the invention, the device can include a processor and a digital memory device capable of storing data.

For purposes of illustration and not limitation, processor 90 is schematically depicted in FIG. 1 connected to digital memory device 92. Processor 90 can be any microprocessor that can be programmed to display messages or graphic representation in accordance with the invention. By using a processor 90 and digital memory device 92, information in addition to that captured by lens 50 can be displayed by light emitting devices 70. For example, device 20 can be configured to display an image of an observer in superposition with a second image, the second image being stored in the digital memory device 92 and displayed using the light emitting devices 70 by the processor 90. Processor 90 is also provided with a timer 94 in order to enable it to activate the light-emitting devices 70 at predetermined time intervals to display a superimposed message and/or graphic representation (e.g. a logo) to an observer.

Processor 90 can be programmed to illuminate light emitting devices 70 in a number of ways. As can be seen in FIG. 5, light emitting devices 70 are spaced radially from one another, such that a light emitting device 70 spaced further from the center of rotation of device 20 than another light emitting device will be traveling at a slightly faster tangential velocity. Under certain circumstances, such as where light emitting devices 70 have a large distance between them in a radial direction, this tangential velocity difference can affect the quality of the image displayed by the user by causing the “top” of an image to “spread out.” Thus, it may be desirable under certain circumstances to illuminate more inwardly located light emitting devices 70 for a shorter time than ones located radially outward away from the center of rotation. As with power source 80, processor 90 and digital memory device 92 can be located in housing 54 or radial member 60.

In accordance with a further aspect of the invention, the device can be provided with a position sensor to sense the position that the device is moving at when being used.

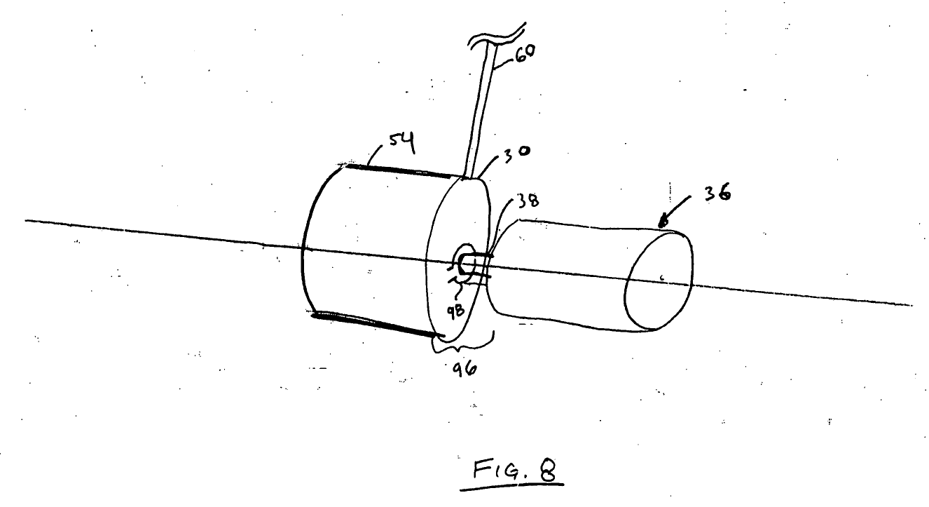

For purposes of illustration and not limitation, as depicted in FIG. 8, position sensor 96 is depicted herein as a rotational potentiometer 98 mounted to a stationary portion of motor 36 and hub 30 to measure relative rotational displacement between the two. This permits determination of the angular position of housing 54 with respect to motor 36. In accordance with this aspect of this invention, processor 90 and timer 94 are configured to measure the rotational speed of the device 20 while in use by continuously measuring the potential difference across the potentiometer to determine the speed of angular displacement, or rotational speed, of device 20. In this manner it is possible for the sequencing of the light-emitting devices to change as the rotational speed of the device changes. This can facilitate displaying a superimposed message as described above to an observer.

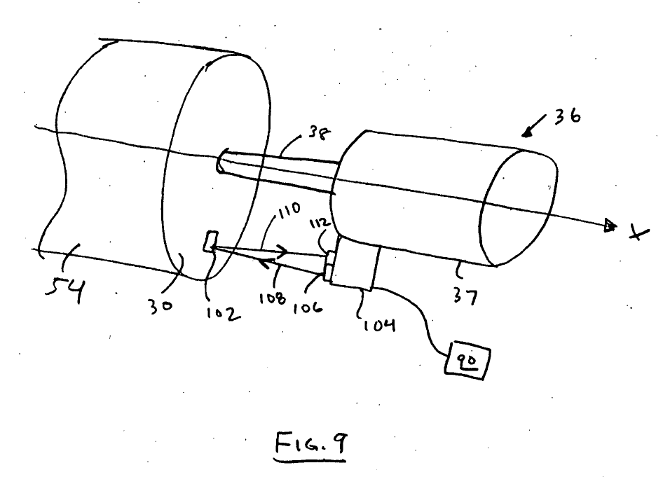

A variety of other devices can be provided to measure the angular velocity of device 20 when it is rotated. Instead of potentiometer 98, a magnet and magnet detector (not shown) can be used. Similarly, a reflective surface 102 can be provided on hub 30 and an infrared (“IR”)-LED module 104 can be provided on a stationary portion such as housing 37 of motor 36, respectively, to measure the frequency of rotation. As depicted in FIG. 9, IR signal is launched from transmit portion 106 of module 104, and is reflected by reflective surface 102 when reflective surface 102 passes through the path 108 of the IR transmit beam. Reflected beam 110 then passes to receive portion 112 of module 104. In response to receiving signal 112, module 104 provides an electrical signal to processor 90 to allow processor 90 to calculate the rotational velocity of housing 54. As with potentiometer 98, the magnet detector or IR-LED module can be interfaced with processor 90 to properly time the display of superimposed images. Moreover, the AC electrical signal of the motor 36 can be measured to measure the rotational speed of device 20. This can be accomplished if processor 90 is configured to measure the sinusoidal variation in voltage of the motor 36 over time. One full rotation of device 20 will result in a complete cycle (e.g., a voltage trace over time resembling a sine wave of period 2JI). Thus, processor 90 can accomplish this time-varying voltage measurement via correlation with the output of timer 94 (or can be provided with its own timer) to measure the rotational speed of device 20 while in use.

In further accordance with the invention, a device can be provided as described above further including an acoustic emitter. In accordance with one embodiment of the invention, a speaker (not shown) is provided to emit one or more sounds. A speaker may be provided to emit an indicator sound (e.g., a “beep”) during use of device 20. Sounds may also be emitted by device 20 as a supplement to the visual display that can be produced with device 20. Any sounds can be programmed to be emitted by into device 20. For example, at trade shows theme music can be emitted by device 20. These sounds can be stored permanently on digital memory device 92 or can be programmed into device 20 via cable or wireless connection, even while device 20 is being used.

In further accordance with the invention, a system is provided including a device for displaying images as disclosed herein and an additional component.

For example, device 20 can be configured to be permanently attached to computer (not shown). Applications for such a system can include, for example, a permanent display in a store window or at a trade show, and the like.

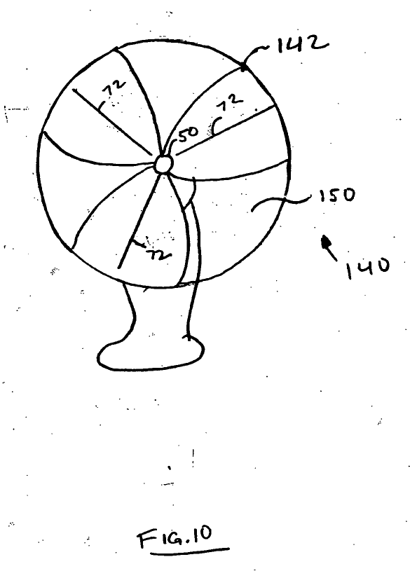

Device 20 can also be integrated into a fan 140, as depicted in FIG. 10 with lens 50 at the center thereof. When the fan 140 is used, light-emitting devices 70 disposed radially in rows 72 along one or more fan blades 142 are activated to display a “reflection” to a user as described above. The fan 140 can be configured to display superimposed messages as described above. Moreover, fan 140 can be programmed to display different messages and/or emit different sounds using a remote control (not shown). In accordance with this aspect of the invention, fan 140 can be provided with an infrared (“IR”) receiver. While a table top fan is depicted, other types of fans, such as ceiling fans can be integrated with device 20.

In further accordance with the invention, a method is provided for displaying images using a device as described herein. The method includes providing a device as described above, operating the motor to rotate the hub about the first axis, directing light toward the light detecting devices using the at least one lens, generating an electrical signal by detecting at least a portion of the directed light using the light detecting devices, directing the electrical signal through one or more electrically conductive elements to the light-emitting devices, and emitting light from the light emitting devices. Any of the devices embodied herein can be used to practice this method.

In further accordance of the method of the invention, the device can be configured to emit light at more than one wavelength, thus permitting the emission of light in one or more colors. For purposes of illustration and not limitation, as embodied herein and as shown in FIG. 5, three rows of light emitting devices 70 can be provided in each radial member 60, wherein light emitting devices 70 in a first row 72(a) emits green light, light emitting devices 70 in a second row 72(b) emits blue light, and light emitting devices 70 in a third row 72(c) emits red light. The combination of these three colors can be used to provide a full color rasterized image to an observer. In further accordance with this aspect of the invention, rows 42 of light detecting devices 40 will necessarily comprise three rows of light detecting elements sensitive to red, green, and blue light, respectively, thus permitting detection of a color image that can be redisplayed through red, green, and blue light emitting devices 70, respectively.

An example of a device made in accordance with the teachings herein is described in the Example below.

### EXAMPLE I

An exemplary embodiment of device 20 is depicted in FIG. 1. Device 20 includes eighty circuits similar to the one depicted in FIG. 6. Thus, device 20 includes 80 photodiodes, 80 light emitting diodes, and 160 resistors. 5V electrical power is provided to device 20 by routing the power through the motor shaft 38 and motor housing 37/bearing 39 as described above. A single lens 50 is provided to focus an image to be redisplayed, or “reflected” to the observer. Thus, row 42 of light detecting devices 40 is offset 180 degrees from a row 72 of light emitting devices 72. As device 20 rotates, the light detecting devices 40 sweep through a circular plane and cause corresponding light emitting devices 70 in radial members 60 to light. If device 20 is rotating quickly enough, this results in light emitting devices 70 producing a rasterized image of the observer.

It will be apparent to those skilled in the art that various modifications and variations can be made in the method and system of the present invention without departing from the spirit or scope of the invention. Thus, it is intended that the present invention include modifications and variations that are within the scope of the appended claims and their equivalents.

What is claimed is:

1. A device for displaying images, comprising:
a hub configured to rotate about a first axis;
a motor connected to the hub, the motor configured to rotate the hub about the first axis;
a plurality of light detecting devices attached to the hub;
at least one lens configured to direct light toward the light detecting devices;
at least one radial member oriented along a radial axis, the radial member having a first end attached to the hub and a second end, the radial member including a plurality of light-emitting devices disposed therein, the light emitting devices being oriented along the radial axis;
a power source operably coupled to the motor, power source and light-emitting devices, wherein the light emitting devices emit light in response to light received by the light detecting devices.

2. The device of claim 1, wherein each of the light detecting devices is electrically connected to one or more of the light-emitting devices.

3. The device of claim 2, wherein at least one transistor is placed in a circuit with each of the light detecting devices and light emitting devices.

4. The device of claim 1, wherein each of the light detecting devices are configured to emit light at one or more preselected wavelengths.

5. The device of claim 4, wherein the light emitting devices are configured to emit light in a color selected from the group consisting of red, green and blue.

6. The device of claim 5, wherein the light emitting devices are configured to emit light in red, green and blue.

7. The device of claim 6, wherein the light emitting devices are liquid crystal display devices.

8. The device of claim 6, wherein the light emitting devices include one or more thin-film transistor display devices.

9. The device of claim 6, wherein the light emitting devices include a flexible polymer display device.

10. The device of claim 6, wherein the light emitting devices include organic light emitting diodes.

11. The device of claim 1, wherein the device includes a plurality of lenses configured to direct light toward the light detecting devices.

12. The device of claim 11, wherein the plurality of lenses are arranged in a manner to create a collimated beam of light that is directed toward the light detecting devices.

13. The device of claim 1, further comprising at least one fiber optic filament, the filament having a first end in optical communication with light directed by the at least one lens and a second end in optical communication with the light detecting devices.

14. The device of claim 13, wherein the device includes a plurality of fiber optic filaments, the at least one lens being in optical communication with the plurality of fiber optic filaments.

15. The device of claim 13, wherein the device includes a plurality of lenses, and at least one of the plurality of lenses is in optical communication with a second end of the at least one fiber optic filament.

16. A system comprising the device of claim 1, wherein the device is mounted to a rotating device.

17. The system of claim 16, wherein the rotating device is a fan.

18. The device of claim 1, further including a processor and a digital memory device capable of storing data.

19. The device of claim 18, wherein the device is configured to display an image of an observer in superposition with a second image, the second image being stored in the digital memory device and displayed on the light emitting devices by the processor.

20. A method for displaying an image, comprising:
providing a device in accordance with claim 1;
operating the motor to rotate the hub about the first axis;
directing light toward the light detecting devices using the at least one lens;
generating an electrical signal by detecting at least a portion of the directed light using the light detecting devices;
directing the electrical signal through one or more electrically conductive elements to the light-emitting devices;
emitting light from the light emitting devices.
